(19) United States
(12) Patent Application Publication
(10) Pub. No.: US 2025/0116711 A1
(43) Pub. Date: Apr. 10, 2025

(54) BATTERY PACK, METHOD OF MEASURING CHARGE CURRENT OF THE SAME, AND CHARGE CURRENT MEASUREMENT SYSTEM

(71) Applicant: SAMSUNG SDI CO., LTD., Yongin-si (KR)

(72) Inventor: Young Dong SEO, Suwon-si (KR)

(21) Appl. No.: 18/392,337

(22) Filed: Dec. 21, 2023

(30) Foreign Application Priority Data
Oct. 6, 2023 (KR) 10-2023-0133095

(51) Int. Cl. G01R 31/382; H02J 7/00

(52) U.S. Cl. CPC G01R 31/382; H02J 7/0013; H02J 7/0047

(57) ABSTRACT

A battery pack includes a battery module including battery cells, a current measurement module measuring a charge current supplied to the battery module, and a processor. Upon detecting connection of a charger to the battery pack, the processor sets a sinusoidal waveform charge current frequency supplied from the charger to the battery module as first frequency, recognizes the charge current frequency based on a charge current value measured through a current measurement module according to a first number of sampling times for one cycle set to the first frequency, and adjusts the number of sampling times for one cycle based on the recognized frequency of the charge current. A corresponding charge current measuring method of measuring a charge current and a charge current measurement systems are also provided.

### CROSS-REFERENCE TO RELATED APPLICATION

The present application claims the benefit of Korean Patent Application No. 10-2023-0133095, filed on Oct. 6, 2023 in the Korean Intellectual Property Office, the entire disclosure of which is incorporated herein by reference.

### BACKGROUND

### 1. Field

Aspects of embodiments of the present disclosure relate to a battery pack enabling measurement of a sinusoidal waveform charge current, a method of measuring a charge current of the same, and a charge current measurement system.

### 2. Description of the Related Art

Typically, light electric vehicles (LEVs) including golf carts or energy storage systems (ESSs) employ constant current (CC)-constant voltage (CV) charging and some chargers supply a charge current in a sinusoidal current pattern. In this case, the frequency of sinusoidal waves is twice an input frequency of charger AC.

Upon charging a battery pack using a charger that supplies a charge current in a sinusoidal current pattern, a battery management system (BMS) performs sampling in measurement of the current, causing less measurement accuracy than CC-CV charging.

Moreover, upon charging a battery pack using the charger that supplies a charge current in the sinusoidal current pattern, there is a problem of deterioration in current measurement accuracy due to a current measurement cycle. That is, since the current measurement cycle (for example, 25 ms) of the BMS is three times a charge current cycle (for example, 8.3 ms) of the charger, there is a possibility of continuous mismeasurement of the current. For example, when the current is measured at the peak of the current, the current will be continuously measured only at the peak, and when the current is measured at the trough of the current, the current will be continuously measured only at the trough, thereby causing deterioration in current measurement accuracy.

Moreover, when charging a battery pack using the charger that supplies a charge current in the sinusoidal current pattern, there is a problem of difficulty in ensuring accurate measurement of the charge current due to different frequencies of AC by country.

This section provides background information related to the present invention which is not necessarily prior art.

### SUMMARY

Embodiments are directed to, in a first aspect, a battery pack including: a battery module including a plurality of battery cells; a current measurement module measuring a charge current supplied to the battery module; and a processor. Upon detecting connection of a charger to the battery pack, the processor may: set a frequency of a sinusoidal waveform charge current supplied from the charger to the battery module to a first frequency; recognize the frequency of the charge current based on a charge current value measured through a current measurement module according to a first number of sampling times for one cycle set to the first frequency, and adjust the number of sampling times for one cycle based on the recognized frequency of the charge current.

The battery pack of the first aspect, wherein the processor may detect that the charger may be connected to the battery pack, upon detecting a charger interlock or upon receiving a charger connection signal from the charger.

The battery pack of the first aspect, wherein the processor may recognize the frequency of the charge current based on a difference between the first measured charge current value and the last measured charge current value among charge current values measured for the one cycle. The battery pack of the first aspect, wherein the processor may: determine that the frequency of the charge current may be the first frequency when the difference between the first measured charge current value and the last measured charge current value may be less than a preset threshold; and determine that the frequency of the charge current may be a second frequency when a case where the difference between the first measured charge current value and the last measured charge current value may be greater than or equal to the preset threshold may be detected a preset number of times or more. The battery pack of the first aspect, wherein the processor may adjust the number of sampling times for one cycle to a second number of sampling times set to the second frequency, upon determining that the frequency of the charge current may be the second frequency.

The battery pack of the first aspect, wherein the processor may: calculate an average of the charge current values measured for the one cycle through the current measurement module according to the adjusted number of sampling times; and determine the average as the charge current of the battery module.

Embodiments are directed to, in a second aspect, a method of measuring a charge current of a battery pack including a battery module, a current measurement module, and a processor. The method includes: upon detecting connection of a charger to the battery pack, setting, by the processor, a frequency of a sinusoidal waveform charge current supplied from the charger to the battery module to a first frequency; recognizing, by the processor, the frequency of the charge current based on a charge current value measured through a current measurement module according to a first number of sampling times for one cycle set to the first frequency; and adjusting, by the processor, the number of sampling times for one cycle based on the recognized frequency of the charge current.

The method of the second aspect, wherein, in the step of setting to the first frequency, the processor detects that the charger may be connected to the battery pack, upon detecting a charger interlock or upon receiving a charger connection signal from the charger.

The method of the second aspect, wherein, in the step of recognizing the frequency of the charge current, the processor recognizes the frequency of the charge current based on a difference between the first measured charge current value and the last measured charge current value among charge current values measured for the one cycle.

The method of the second aspect, wherein, in the step of recognizing the frequency of the charge current, the processor determines that the frequency of the charge current may be the first frequency when the difference between the first measured charge current value and the last measured charge current value may be less than a preset threshold, and determines that the frequency of the charge current may be a second frequency when a case where the difference between the first measured charge current value and the last measured charge current value may be greater than or equal to the preset threshold may be detected a preset number of times or more. The method of the second aspect, wherein, in the step of adjusting the number of sampling times for one cycle, the processor adjusts the number of sampling times for one cycle to a second number of sampling times set to the second frequency, upon determining that the frequency of the charge current may be the second frequency.

The method of the second aspect, further including: after the step of adjusting the number of sampling times for one cycle, calculating, by the processor, an average of the charge current values measured for the one cycle through the current measurement module according to the adjusted number of sampling times, followed by determining the average as the charge current of the battery module.

Embodiments are directed to, in a third aspect, a charge current measurement system including: a battery pack including a battery module, a current measurement device, and a processor; and a charger adapted to supply a sinusoidal waveform charge current to the battery module when connection of the charger to the battery pack may be detected, wherein the processor may: set a frequency of a sinusoidal waveform charge current supplied from the charger to the battery module to a first frequency; recognize the frequency of the charge current based on a charge current value measured through a current measurement module according to a first number of sampling times for one cycle set to the first frequency; and adjust the number of sampling times for one cycle based on the recognized frequency of the charge current.

The charge current measurement system of the third aspect, wherein the processor may recognize the frequency of the charge current based on a difference between the first measured charge current value and the last measured charge current value among charge current values measured for the one cycle. The charge current measurement system of the third aspect, wherein the processor may: determine that the frequency of the charge current may be the first frequency when the difference between the first measured charge current value and the last measured charge current value may be less than a preset threshold; and determine that the frequency of the charge current may be a second frequency when a case where the difference between the first measured charge current value and the last measured charge current value may be greater than or equal to the preset threshold may be detected a preset number of times or more. The charge current measurement system of the third aspect, wherein the processor may adjust the number of sampling times for one cycle to a second number of sampling times set to the second frequency, upon determining that the frequency of the charge current may be the second frequency.

However, aspects and features of the present invention are not limited to those described above and other aspects and features not mentioned will be clearly understood by a person skilled in the art from the detailed description given below.

### BRIEF DESCRIPTION OF DRAWINGS

Features will become apparent to those of skill in the art by describing in detail exemplary embodiments with reference to the attached drawings in which:

FIG. 1 is a block diagram of a charge current measurement system according to an embodiment of the present invention;

FIG. 2 is a circuit diagram of a battery pack of the charge current measurement system according to the embodiment of the present invention;

FIGS. 3A and 3B are graphs illustrating examples of a method of recognizing a charge current frequency according to the present invention;

FIG. 4 is a flowchart illustrating a method of measuring a charge current of a battery pack according to an embodiment of the present invention;

FIG. 5 is a graph of an experimental result in measurement of charge current at a current frequency of 100 Hz; and

FIG. 6 is a graph of an experimental result in measurement of charge current at a current frequency of 120 Hz.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

It will be understood that when an element or layer is referred to as being “on,” “connected to,” or “coupled to” another element or layer, it may be directly on, connected, or coupled to the other element or layer or one or more intervening elements or layers may also be present. When an element or layer is referred to as being “directly on,” “directly connected to,” or “directly coupled to” another element or layer, there are no intervening elements or layers present. For example, when a first element is described as being “coupled” or “connected” to a second element, the first element may be directly coupled or connected to the second element or the first element may be indirectly coupled or connected to the second element via one or more intervening elements.

In the figures, dimensions of the various elements, layers, etc. may be exaggerated for clarity of illustration. The same reference numerals designate the same elements. As used herein, the term “and/or” includes any and all combinations of one or more of the associated listed items. Further, the use of “may” when describing embodiments of the present disclosure relates to “one or more embodiments of the present disclosure.” Expressions, such as “at least one of” and “any one of,” when preceding a list of elements, modify the entire list of elements and do not modify the individual elements of the list. When phrases such as “at least one of A, B and C, “at least one of A, B or C,” “at least one selected from a group of A, B and C,” or “at least one selected from among A, B and C” are used to designate a list of elements A, B and C, the phrase may refer to any and all suitable combinations or a subset of A, B and C, such as A, B, C, A and B, A and C, B and C, or A and B and C. As used herein, the terms “use,” “using,” and “used” may be considered synonymous with the terms “utilize,” “utilizing,” and “utilized,” respectively. As used herein, the terms “substantially,” “about,” and similar terms are used as terms of approximation and not as terms of degree, and are intended to account for the inherent variations in measured or calculated values that would be recognized by those of ordinary skill in the art.

It will be understood that, although the terms first, second, third, etc. may be used herein to describe various elements, components, regions, layers, and/or sections, these elements, components, regions, layers, and/or sections should not be limited by these terms. These terms are used to distinguish one element, component, region, layer, or section from another element, component, region, layer, or section. Thus, a first element, component, region, layer, or section discussed below could be termed a second element, component, region, layer, or section without departing from the teachings of example embodiments.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

The terminology used herein is for the purpose of describing embodiments of the present disclosure and is not intended to be limiting of the present disclosure. As used herein, the singular forms “a” and “an” are intended to include the plural forms as well, unless the context clearly indicates otherwise. It will be further understood that the terms “includes,” “including,” “comprises,” and/or “comprising,” when used in this specification, specify the presence of stated features, integers, steps, operations, elements, and/or components but do not preclude the presence or addition of one or more other features, integers, steps, operations, elements, components, and/or groups thereof.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132(a).

References to two compared elements, features, etc. as being “the same” may mean that they are “substantially the same”. Thus, the phrase “substantially the same” may include a case having a deviation that is considered low in the art, for example, a deviation of 5% or less. In addition, when a certain parameter is referred to as being uniform in a given region, it may mean that it is uniform in terms of an average.

Throughout the specification, unless otherwise stated, each element may be singular or plural.

When an arbitrary element is referred to as being disposed (or located or positioned) on the “above (or below)” or “on (or under)” a component, it may mean that the arbitrary element is placed in contact with the upper (or lower) surface of the component and may also mean that another component may be interposed between the component and any arbitrary element disposed (or located or positioned) on (or under) the component.

In addition, it will be understood that when an element is referred to as being “coupled,” “linked” or “connected” to another element, the elements may be directly “coupled,” “linked” or “connected” to each other, or an intervening element may be present therebetween, through which the element may be “coupled,” “linked” or “connected” to another element. In addition, when a part is referred to as being “electrically coupled” to another part, the part can be directly connected to another part or an intervening part may be present therebetween such that the part and another part are indirectly connected to each other.

Throughout the specification, when “A and/or B” is stated, it means A, B or A and B, unless otherwise stated. That is, “and/or” includes any or all combinations of a plurality of items enumerated. When “C to D” is stated, it means C or more and D or less, unless otherwise specified.

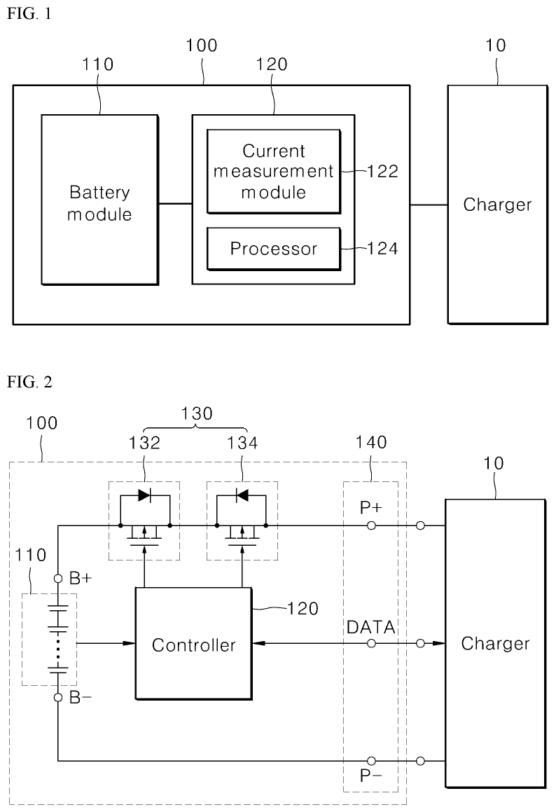

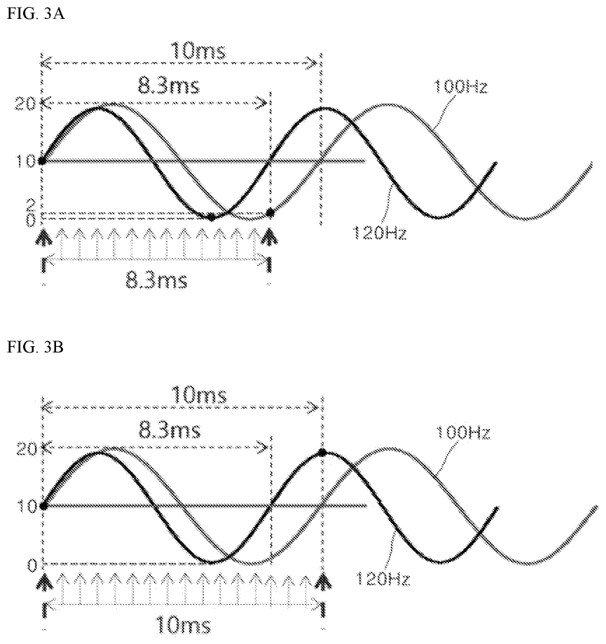

FIG. 1 is a block diagram of a charge current measurement system according to an embodiment of the present invention; FIG. 2 is a circuit diagram of a battery pack of the charge current measurement system according to the embodiment of the present invention; and FIGS. 3A and 3B are graphs of example outcomes of a method of recognizing a charge current frequency according to the present invention.

Referring to FIG. 1 and FIG. 2, a charge current measurement system according to an embodiment of the present invention includes a charger 10 and a battery pack 100.

The charger 10 may supply a sinusoidal waveform charge current to the battery pack 100.

The charger 10 may transmit a predetermined communication signal (for example, a charger connection signal) to the battery pack 100 (for example, to controller 120) while detecting that the charger 10 is connected to the battery pack 100, and may allow the battery pack 100 (for example, the controller 120) to detect that the battery pack 100 is connected to the charger 10. For example, the charger 10 may transmit the communication signal at predetermined intervals while being connected to the battery pack 100.

The charger 10 may change a frequency of a charge current according to an AC input frequency. The frequency of the charge current may be, for example, twice the frequency of the AC input. For example, in Korea, since AC 60 Hz is used, the frequency of the charge current may be 120 Hz, and in the US, since AC 50 Hz is used, the frequency of the charge current may be 100 Hz.

Such a charger 10 may include, for example, an SC-48 charger. One skilled in that art will know that “SC-48” refers to a 48 volt sealed charger.

The battery pack 100 may be connected to the charger 10 through a connector 140 to perform a charging operation of at least one battery module 110. Further, the battery pack 100 may be connected to an external load (now shown) through the connector 140 to perform a discharge operation of the battery module 110. A high current path between the battery module 110 and the connector 140 may be used as a charge/discharge path. Power terminals of the charger 10 or the external load (not shown) may be connected to a first pack terminal P+ and a second pack terminal P− of the connector 140.

According to one embodiment, the battery pack 100 and the charger 10 may include signal lines that can send and receive power and communication signals between the battery pack 100 and the charger 10. For example, a communication part (now shown) of the charger 10 may be connected to a communication terminal DATA of the

The battery pack 100 may include at least one battery module 110, a controller 120, and a protective circuit 130. In various embodiments, the battery pack 100 may further include other components.

The battery module 110 may include a plurality of battery cells and a module housing. The battery module 110 may include a plurality of battery cells connected to each other in series or in parallel. The battery modules 110 may be connected to each other in series or in parallel.

The battery cells may be received in a stacked state within the module housing. Each of the battery cells may have a cathode lead and an anode lead. The battery cells may be, for example, round, prismatic, or pouch type battery cells depending on the shape of the battery.

In the battery pack 100, a single stack of battery cells may form a single module instead of the battery module 110. The cell stack may be received in an accommodation space of a pack housing or in an accommodation space partitioned by a frame, a partition wall, or the like.

The battery cell may generate a large amount of heat during charging and discharging. The heat is accumulated in the battery cells and promotes degradation of the battery cells. Thus, the battery pack 100 may further include a cooling member to suppress degradation of the battery cells. The cooling member may be disposed at a lower part of the accommodation space which receives the battery cells. Alternatively, the cooling member may be also disposed at an upper portion of the accommodation space or on a side surface thereof according to the battery pack 100.

Exhaust gas generated within the battery cell due to abnormal operating conditions, also known as thermal runaway or thermal events of the battery cell, may be discharged outside the battery cell. The battery pack 100 or the battery module 110 may be provided with an exhaust vent or the like to discharge the exhaust gas in order to prevent the exhaust gas from damaging the battery pack 100 or the battery module 110.

The protective circuit 130 may include a charge element 132 and a discharge element 134.

The controller 120 may control charge/discharge of the battery module 110 by detecting voltage of the battery module 110 and controlling operation of the charge element 132 and the discharge element 134. For example, when the battery pack 100 is connected to the charger 10 through the connector 140, the controller 120 may set the charge element 132 to an ON state and the discharge element 134 to an OFF state to allow the battery module 110 to be charged. In addition, when the battery pack 100 is connected to an external system (now shown) through the connector 140, the controller 120 may set the charge element 132 to an OFF state and the discharge element 134 to an ON state to allow the battery module 110 to be discharged.

The charge element 132 and the discharge element 134 may be connected to the high current path between the battery module 110 and the connector 140 and may perform charging or discharging of the battery module 110. The charge element 132 may include a field effect transistor FET 1 and a parasitic diode D1. The discharge element 134 may include a field effect transistor FET 2 and a parasitic diode D2. A connection direction between a source and a drain of FET 1 may be set in an opposite direction to that of FET 2. In this configuration, FET 1 may limit current flow from the connector 140 to the battery module 110, while FET 2 may be connected to limit current flow from the battery module 110 to the connector 140. D1 and D2 may be configured to allow electric current to flow in an opposite direction to a direction in which the electric current is limited.

The connector 140 may be connected to the battery module 110 and may be connected to the charger 10 to operate as a terminal for charging the battery module 110 upon charging. The connector 140 may be connected to an external load (now shown) to operate as a terminal for discharging the battery module 110 upon discharging. To this end, the connector 140 may include the first pack terminal P+ and the second pack terminal P−. The first pack terminal P+ may be a cathode pack terminal connected to a cathode B+ of the battery module 110. The second pack terminal P− may be an anode pack terminal connected to an anode B− of the battery module 110. When the charger 10 is connected to the connector 140, the charger 10 may charge the battery module 110, and when the external load is connected to the connector 140, discharging from the battery module 110 to the external load may be performed.

The connector 140 may include a communication terminal DATA connected to the controller 120. According to one embodiment, when the charger 10 is connected to the connector 140, the communication terminal DATA may enable communication between the controller 120 and the charger 10.

The controller 120 may include a current measurement module 122 and a processor 124. The controller 120 may be provided to a battery management system (BMS).

The current measurement module 122 may measure a charge current supplied from the charger 10 to the battery module 110 under control of the processor 124. The current measurement module 122 may include, for example, a current sensor and the like.

The battery pack 100 according to an embodiment of the invention may further include a shunt resistor (now shown) connected to the high current path between the battery module 110 and the connector 140. For example, the shunt resistor may be connected between the anode B− of the battery module 110 and the second pack terminal P−. Further, the shunt resistor may be connected to the controller 120. Accordingly, the charge current flowing between the battery module 110 and the charger 10 flows through the shunt resistor and the current measurement module 122 may measure the charge current flowing between the entire battery module 110 and the charger 10 from voltage drop caused by the shunt resistor.

Upon detecting connection of the charger 10 to the battery pack, the processor 124 may set a frequency of a sinusoidal waveform charge current supplied from the charger 10 to the battery module 110 to a first frequency, may recognize the frequency of the charge current based on a charge current value measured through the current measurement module 122 according to a first number of sampling times for one cycle set to the first frequency, and may adjust the number of sampling times for one cycle based on the recognized frequency of the charge current. The processor 124 may determine whether the frequency of the charge current is the first frequency or a second frequency based on the charge current value measured (sampled) for the one cycle. The first frequency may be one of 100 Hz and 120 Hz, and the second frequency may be a frequency other than the first frequency selected from among 100 Hz and 120 Hz. In the following embodiments, the first frequency and the second frequency are described as 120 Hz and 100 Hz. However, it should be understood that the first frequency and the second frequency can be realized as various frequencies other than 120 Hz and 100 Hz. For ease of description, the first frequency will be described as 120 Hz and the second frequency will be described as 100 Hz.

Hereinafter, operation of the processor 124 will be described in detail.

The processor 124 may set and store, in a memory, the number of sampling times to be measured for one cycle depending upon the frequency of the sinusoidal waveform charge current supplied from the charger 10 to the battery module 110. In other words, the processor 124 may preset the number of sampling times to be measured for the one cycle in consideration of a measurement time of the charge current value of a battery management device upon application of a charge current of 100 Hz and 120 Hz.

For example, if a single charge current measurement time is set to 0.63 ms, a charge current waveform of 100 Hz can be sampled 17 times for 1 cycle (10 ms) and a charge current waveform of 120 Hz can be sampled 14 times for 1 cycle (8.3 ms). Accordingly, the processor 124 may set the number of sampling times to 17 for one cycle (10 ms) for 100 Hz and to 14 for one cycle (8.3 ms) for 120 Hz. Here, the 17^{th} or 14^{th} charge current value measured (sampled) last may be the first charge current value first measured (sampled) in the next cycle.

Then, when connection of the charger 10 to the battery pack is detected, the processor 124 may assume (set) the frequency of the sinusoidal waveform charge current supplied from the charger 10 to the battery module 110 as the first frequency (for example, 120 Hz). Here, when the charger 10 is supported to communicate with the controller 120, the processor 124 may detect that the charger 10 is connected to the battery pack upon detecting a charger interlock or upon receiving a charger connection signal from the charger 10. The processor 124 may detect connection of the charger 10 by receiving a signal from the communication part (now shown) of the charger 10. For example, the processor 124 may detect connection of the charger 10 based on a predetermined signal transmitted from the communication part of the charger 10.

The charger 10 may not be supported to communicate with the controller 120. In this case, when a sinusoidal waveform charge current supplied from the charger 10 to the battery module 110 is first detected, the processor 124 may assume (set) the frequency of the sinusoidal waveform charge current as the first frequency (for example, 120 Hz).

When the frequency of the sinusoidal waveform charge current is set to the first frequency (for example, 120 Hz), the processor 124 may sample (measure) the charge current value through the current measurement module 122 according to a first number of sampling times for one cycle set to the first frequency.

For example, the processor 124 may sample a charge current waveform of 120 Hz 14 times for 8.3 ms.

When the charge current value is sampled (measured), the first number of sampling times for one cycle set to the first frequency, the processor 124 may recognize the frequency of the charge current based on a difference between the first measured charge current value and the last measured charge current value among charge current values sampled (measured) for the one cycle. Here, the first measured charge current value may be a charge current value measured first among the charge current values measured for the one cycle, and the last measured charge current value may be a charge current value measured last among the charge current values measured for the one cycle. The last measured charge current value may be the first measured charge current value of the next cycle. For example, when a charge current waveform of 120 Hz is sampled (measured) 14 times for one cycle, the 14th measured charge current value may be the first measured charge current value of the next cycle.

Since the charge current has a sinusoidal waveform, the first measured charge current value and the last measured charge current value may be the same or similar values when the charge current is sampled (measured) for exactly one cycle. Thus, the difference between the first measured charge current value and the last measured charge current value may be a value close to zero.

Accordingly, the processor 124 may determine whether the difference between the first measured charge current value and the last measured charge current value is greater than or equal to a preset threshold value, and may recognize the frequency of the charge current to be the first frequency or the second frequency based on a determination result. Here, the difference between the first measured charge current value and the last measured charge current value may be an absolute value and the threshold value may be an arbitrary value, for example, 1 A.

When the difference between the first measured charge current value and the last measured charge current value is less than the threshold value, the processor 124 may determine that the frequency of the charge current is the first frequency.

When the difference between the first measured charge current value and the last measured charge current value is greater than or equal to the threshold value, the processor 124 may determine whether the case where the difference between the first measured charge current value and the last measured charge current value is greater than or equal to the threshold value, is continuously detected a preset number of times or more.

In other words, since errors can occur in sampling (measurement) of the charge current, the processor 124 does not need to eliminate such errors. Accordingly, the processor 124 may determine whether the case where the difference between the first measured charge current value and the last measured charge current value is greater than or equal to the threshold value is continuously detected a certain number of times. Here, the certain number of times may be a preset value, for example, 3 times, 4 times, 10 times, or the like.

If the case where the difference between the first measured charge current value and the last measured charge current value is greater than or equal to the threshold value is continuously detected the certain number of times or more, the processor 124 may determine that the frequency of the charge current is the second frequency rather than the first frequency. Upon determining that the frequency of the charge current is the second frequency, the processor 124 may adjust the number of sampling times for one cycle to a second number of sampling times set to the second frequency.

For example, when the number of sampling times is set to 17 for 1 cycle (10 ms) for 100 Hz and to 14 for 1 cycle (8.3 ms) for 120 Hz, a method of adjusting the number of sampling times according to the frequency of the charge current will be described with reference to FIGS. 3A and 3B.

Referring to FIG. 3A, when a charge current waveform of 100 Hz is sampled 14 times for 8.3 ms under the assumption that the frequency of the charge current is 120 Hz, a difference between the first measured charge current value (10 A) and the 14th measured charge current value (2 A) may be 8 A. In this case, since the difference (8 A) between the two charge current values is greater than the threshold value (1 A), the processor 124 may determine that the frequency of the charge current is 100 Hz rather than 120 Hz. Then, the processor 124 may sample the charge current waveform 17 times for one cycle (10 ms). When the charge current waveform of 100 Hz is measured (sampled) 17 times for 10 ms, a difference between the first measured charge current value (10 A) and the 14^{th} measured charge current value (10 A) may be 0 A. In this case, since the difference (0 A) between the two charge current values is less than the threshold value (1 A), it can be confirmed that the frequency of the charge current is 100 Hz.

Referring to FIG. 3B, when a charge current waveform of 120 Hz is sampled (measured) 17 times for 10 ms under under the assumption that the frequency of the charge current is 100 Hz, a difference between the first measured charge current value (10 A) and the 17^{th} measured charge current value (20 A) may be 10 A. In this case, since the difference (10 A) between the two charge current values is greater than the threshold value (1 A), the processor 124 may determine that the frequency of the charge current is 120 Hz rather than 100 Hz. Then, the processor 124 may sample (measure) the charge current waveform 14 times for one cycle (8.3 ms). When the charge current waveform of 120 Hz is sampled (measured) 14 times for 8.3 ms, the difference between the first measured charge current value (10 A) and the 14^{th} measured charge current (10 A) may be 0 A. In this case, since the difference (0 A) between the two charge current values is less than the threshold value (1 A), it can be confirmed that the frequency of the charge current is 120 Hz.

Thereafter, the processor 124 may calculate an average of the charge current values measured for the one cycle through the current measurement module 122 according to the adjusted number of sampling times, and may determine the average as the charge current of the battery module 110.

Here, the processor 124 may be realized, for example, as a central processing unit (CPU) or a system-on-chip (SoC), may execute an operating system or application to control a plurality of hardware and/or software components connected to the processor 124, and may perform various data processing and computations. The processor 124 may be configured to execute at least one instruction stored in a memory (not shown) and to store result data of execution in the memory.

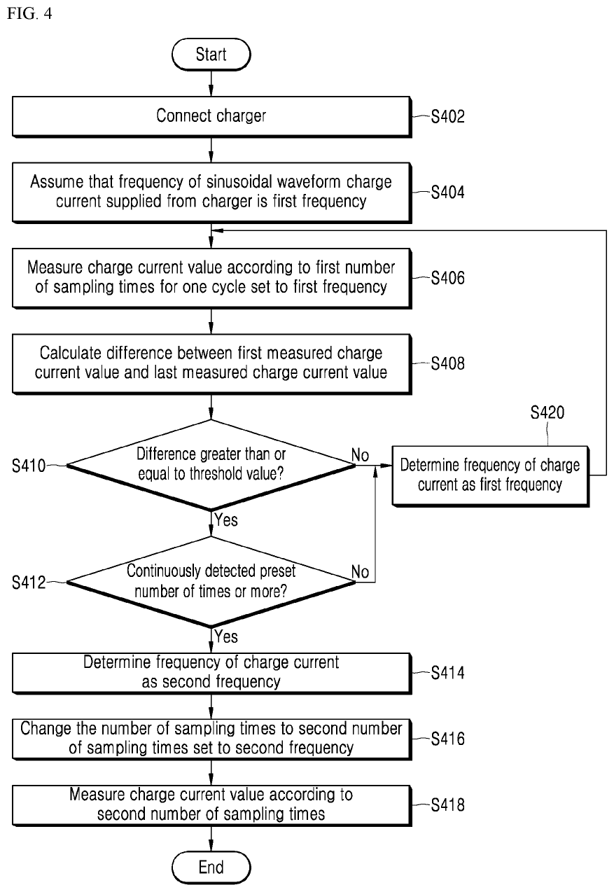

FIG. 4 is flowchart illustrating a method of measuring a charge current of a battery pack according to an embodiment of the present invention.

Referring to FIG. 4, when the charger 10 is connected to the battery pack (step S402), the processor 124 assumes that the frequency of a sinusoidal waveform charge current supplied from the charger 10 to the battery pack is a first frequency (for example, 120 Hz) (step S404). Here, the charger 10 may be supported or may not be supported to communicate with the controller 120. When the charger 10 is supported to communicate with the controller 120, the processor 124 may recognize that the charger 10 is connected to the battery pack upon detecting a charger interlock or upon receiving a charger connection signal from the charger 10. When the charger 10 is not supported to communicate with the controller 120, the processor 124 may recognize that the charger 10 is connected to the battery pack and may assume (set) the frequency of the sinusoidal waveform charge current as the first frequency (120 Hz), upon first detecting the sinusoidal waveform charge current supplied from the charger 10 to the battery module 110.

After step S404, the processor 124 may measure (sample) the charge current value through the current measurement module 122 according to a first number of sampling times for one cycle set to the first frequency (step S406). That is, the processor 124 may measure (sample) the charge current value the first number of sampling times set to the first frequency for one cycle of the sinusoidal waveform.

For example, if the number of sampling times is set to 14 for one cycle (8.3 ms) for 120 Hz, the processor 124 may sample (measure) the charge current waveform of 120 Hz 13 times for 8.3 ms.

After step S406, the processor 124, may calculate a difference between the first measured charge current value and the last measured charge current value among charge current values sampled (measured) for the one cycle (step S408), and determines whether the calculated difference is greater than or equal to a threshold value (inquiry S410). Here, the difference between the first measured charge current value and the last measured charge current value may be an absolute value.

Upon determining in inquiry S410 that the difference between the first measured charge current value and the last measured charge current value is greater than or equal to the threshold value, the processor 124 may determine whether the case where the difference between the two measured charge current values is greater than or equal to the threshold value is continuously detected a preset number of times or more (inquiry S412). Here, the processor 124 may determine whether the case where the difference between the first measured charge current value and the last measured charge current value is greater than or equal to the threshold value, is continuously detected a preset number of times or more in order to eliminate errors that can occur upon sampling (measurement) of the charge current.

Upon determining in inquiry S412 that the case where the difference between the two measured charge current values is greater than or equal to the threshold value is detected a certain number of times, the processor 124 may determine that the frequency of the charge current is a second frequency (step S414) and changes the number of sampling times to a second number of sampling times set to the second frequency (step S416).

After step S416, the processor 124 may measure the charge current values through the current measurement module 122 according to the second number of sampling times (step S420). Thereafter, the processor 124 may calculate an average of the charge current values measured for the one cycle according to the second number of sampling times, and may determine the average as the charge current of the battery module 110.

Upon determining in inquiry S412 that the case where the difference between the two measured charge current values is greater than or equal to the threshold value is not continuously detected a certain number of times, the processor 124 may determine that the frequency of the charge current is the first frequency (step S420), and the method may return to step S406.

Upon determining in inquiry S410 that the difference between the first measured charge current value and the last measured charge current value is not greater than the threshold value, the processor 124 may determine that the frequency of the charge current is the first frequency (step S420), and the method may return to step S406. That is, when the frequency of the charge current is the first frequency, the processor 124 may continue to measure (sample) the charge current values according to the first number of sampling times.

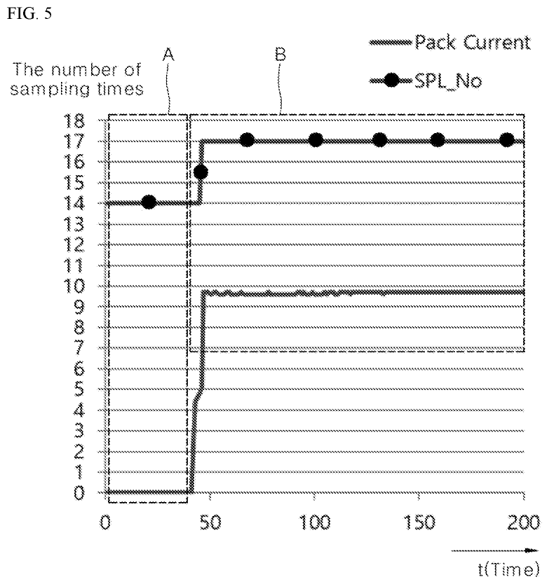

FIG. 5 is a graph showing an experimental result in measurement of charge current at a current frequency of 100 Hz.

FIG. 5 is a graph showing an experimental result in measurement of charge current values under conditions that 100V/50 Hz is applied to the charger 10 and the frequency of a charge current is set to 100 Hz. Referring to FIG. 5, the processor 124 may sample the charge current value 14 times for one cycle under the assumption that the frequency of the charge current in an initial region A is 120 Hz. Then, when the frequency of the charge current is recognized to be 100 Hz rather than 120 Hz, the processor 124 may change the number of sampling times to 17. Next, when the charge current value is sampled 17 times for one cycle as in Region B, it can be confirmed that the charge current remains constant. Here, the amplitude of the charge current may be about 100 mA.

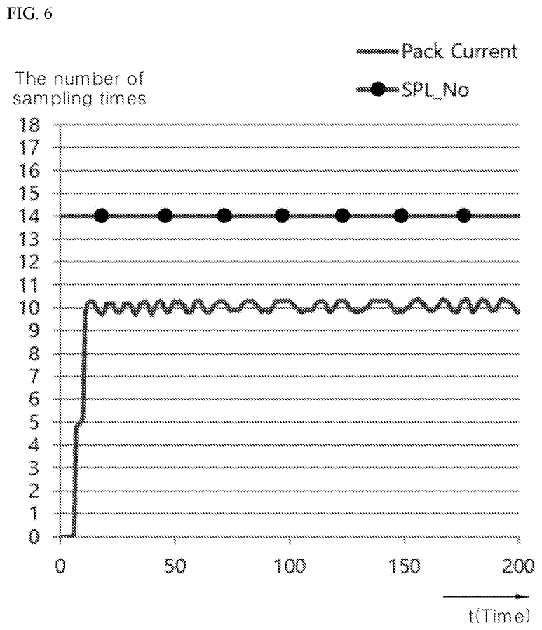

FIG. 6 is a graph showing an experimental result in measurement of charge current at a current frequency of 120 Hz.

FIG. 6 is a graph showing an experimental result in measurement of charge current values under conditions that 110V/60 Hz is applied to the charger 10 and the frequency of a charge current may be set to 120 Hz. Referring to FIG. 6, the processor 124 may sample the charge current value 14 times for one cycle under the assumption that the frequency of the charge current is 120 Hz. Then, when the frequency of the charge current is recognized to be 120 Hz, the processor 124 may sample the charge current value 14 times for one cycle. By sampling the charge current value 14 times for one cycle, it can be confirmed that the charge current remains relatively constant. Here, the amplitude of the charge current may be about 500 mA.

As described above, according to the present invention, it is possible to achieve accurate measurement of a sinusoidal waveform charge current using a charger adapted to charge a battery pack with the sinusoidal waveform charge current.

According to the present invention, it is possible to improve performance of a BMS (fuel gauge, protection, etc.) through accurate measurement of a sinusoidal waveform charge current regardless of frequency.

The embodiments described herein may be implemented, for example, as a method or process, a device, a software program, a data stream, or a signal. Although discussed in the context of a single type of implementation (for example, discussed only as a method), features discussed herein may also be implemented in other forms (for example, a device or a program). The device may be implemented by suitable hardware, software, firmware, and the like. The method may be implemented on a device, such as a processor that generally may refer to a processing device including a computer, a microprocessor, an integrated circuit, a programmable logic device, etc. The processor includes a communication device such as a computer, a cell phone, a personal digital assistant (PDA), and other devices that facilitate communication of information between the device and end-users.

It is an aspect of the present invention to provide a battery pack, a method of measuring a charge current of the same, and a charge current measurement system, which enable accurate measurement of a sinusoidal waveform charge current using a charger adapted to charge a battery pack with the sinusoidal waveform charge current.

The above and other aspects and features of the present invention will be described in or will be apparent from the following description of embodiments of the present invention.

In accordance with one aspect of the present invention, under the assumption that a frequency of a sinusoidal waveform charge current is a first frequency, a battery pack can accurately recognize the frequency of the sinusoidal waveform charge current based on a charge current value measured a first number of sampling times for one cycle set to the first frequency.

According to the present invention, it is possible to achieve accurate measurement of a sinusoidal waveform charge current using a charger adapted to charge a battery pack with a sinusoidal waveform charge current.

According to the present invention, it is possible to improve performance of a BMS (fuel gauge, protection, and the like) through accurate measurement of a sinusoidal waveform charge current regardless of frequency.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A battery pack comprising:
a battery module comprising a plurality of battery cells;
a current measurement module measuring a charge current supplied to the battery module; and
a processor,
wherein, upon detecting connection of a charger to the battery pack, the processor sets a frequency of a sinusoidal waveform charge current supplied from the charger to the battery module to a first frequency, recognizes the frequency of the charge current based on a charge current value measured through a current measurement module according to a first number of sampling times for one cycle set to the first frequency, and adjusts the number of sampling times for one cycle based on the recognized frequency of the charge current.

2. The battery pack as claimed in claim 1, wherein the processor detects that the charger is connected to the battery pack, upon detecting a charger interlock or upon receiving a charger connection signal from the charger.

3. The battery pack as claimed in claim 1, wherein the processor recognizes the frequency of the charge current based on a difference between the first measured charge current value and the last measured charge current value among charge current values measured for the one cycle.

4. The battery pack as claimed in claim 3, wherein the processor determines that the frequency of the charge current is the first frequency when the difference between the first measured charge current value and the last measured charge current value is less than a preset threshold, and determines that the frequency of the charge current is a second frequency when a case where the difference between the first measured charge current value and the last measured charge current value is greater than or equal to the preset threshold is detected a preset number of times or more.

5. The battery pack as claimed in claim 4, wherein the processor adjusts the number of sampling times for one cycle to a second number of sampling times set to the second frequency, upon determining that the frequency of the charge current is the second frequency.

6. The battery pack as claimed in claim 1, wherein the processor calculates an average of the charge current values measured for the one cycle through the current measurement module according to the adjusted number of sampling times, and determines the average as the charge current of the battery module.

7. A method of measuring a charge current of a battery pack including a battery module, a current measurement module, and a processor, the method comprising: upon detecting connection of a charger to the battery pack,
setting, by the processor, a frequency of a sinusoidal waveform charge current supplied from the charger to the battery module to a first frequency;
recognizing, by the processor, the frequency of the charge current based on a charge current value measured through a current measurement module according to a first number of sampling times for one cycle set to the first frequency; and
adjusting, by the processor, the number of sampling times for one cycle based on the recognized frequency of the charge current.

8. The method as claimed in claim 7, wherein, in the step of setting to the first frequency, the processor detects that the charger is connected to the battery pack, upon detecting a charger interlock or upon receiving a charger connection signal from the charger.

9. The method as claimed in claim 7, wherein, in the step of recognizing the frequency of the charge current, the processor recognizes the frequency of the charge current based on a difference between the first measured charge current value and the last measured charge current value among charge current values measured for the one cycle.

10. The method as claimed in claim 9, wherein, in the step of recognizing the frequency of the charge current,
the processor determines that the frequency of the charge current is the first frequency when the difference between the first measured charge current value and the last measured charge current value is less than a preset threshold, and determines that the frequency of the charge current is a second frequency when a case where the difference between the first measured charge current value and the last measured charge current value is greater than or equal to the preset threshold is detected a preset number of times or more.

11. The method as claimed in claim 10, wherein, in the step of adjusting the number of sampling times for one cycle, the processor adjusts the number of sampling times for one cycle to a second number of sampling times set to the second frequency, upon determining that the frequency of the charge current is the second frequency.

12. The method as claimed in claim 7, further comprising: after the step of adjusting the number of sampling times for one cycle,
calculating, by the processor, an average of the charge current values measured for the one cycle through the current measurement module according to the adjusted number of sampling times, followed by determining the average as the charge current of the battery module.

13. A charge current measurement system comprising:
a battery pack comprising a battery module, a current measurement device, and a processor; and
a charger adapted to supply a sinusoidal waveform charge current to the battery module when connection of the charger to the battery pack is detected,
wherein the processor sets a frequency of a sinusoidal waveform charge current supplied from the charger to the battery module to a first frequency, recognizes the frequency of the charge current based on a charge current value measured through a current measurement module according to a first number of sampling times for one cycle set to the first frequency, and adjusts the number of sampling times for one cycle based on the recognized frequency of the charge current.

14. The charge current measurement system as claimed in claim 13, wherein the processor recognizes the frequency of the charge current based on a difference between the first measured charge current value and the last measured charge current value among charge current values measured for the one cycle.

15. The charge current measurement system as claimed in claim 14, wherein the processor determines that the frequency of the charge current is the first frequency when the difference between the first measured charge current value and the last measured charge current value is less than a preset threshold, and determines that the frequency of the charge current is a second frequency when a case where the difference between the first measured charge current value and the last measured charge current value is greater than or equal to the preset threshold is detected a preset number of times or more.

16. The charge current measurement system as claimed in claim 15, wherein the processor adjusts the number of sampling times for one cycle to a second number of sampling times set to the second frequency, upon determining that the frequency of the charge current is the second frequency.
